(19) United States
(12) Patent Application Publication
(10) Pub. No.: US 2016/0164666 A1
(43) Pub. Date: Jun. 9, 2016

(54) CLOCK AND DATA RECOVERY CIRCUIT AND SYSTEM USING THE SAME

(71) Applicant: SK hynix Inc., Icheon-si Gyeonggi-do (KR)

(72) Inventor: Hyun Bae LEE, Icheon-si Gyeonggi-do (KR)

(21) Appl. No.: 14/665,036

(22) Filed: Mar. 23, 2015

(30) Foreign Application Priority Data
Dec. 5, 2014 (KR) 10-2014-0174447

(51) Int. Cl. H04L 7/033; H03L 7/08

(52) U.S. Cl. CPC H04L 7/033; H03L 7/0807

(57) ABSTRACT

A clock and data recovery circuit may include a phase detection unit, a first filtering unit, a second filtering unit, and a phase interpolation unit. The phase detection unit compares a clock signal with data and generates a plurality of early phase detection signals and a plurality of late phase detection signals. The first filtering unit generates an early enable signal and a late enable signal based on the number of early phase detection signals and the number of late phase detection signals that have been generated. The second filtering unit generates an up signal and a down signal based on a difference between the number of times that the early enable signal has been generated and the number of times that the late enable signal has been generated. The phase interpolation unit controls the phase of the clock signal according to the up signal and the down signal.

### CROSS-REFERENCES TO RELATED APPLICATION

The present application claims priority under 35 U.S.C. §119(a) to Korean application number 10-2014-0174447, filed on Dec. 5, 2014, in the Korean Intellectual Property Office, which is incorporated herein by reference in its entirety.

### BACKGROUND

1. Technical Field

Various embodiments generally relate to a semiconductor device, and more particularly, to a clock and data recovery circuit and a system using the same.

2. Related Art

In general, a system which performs serial data communication through a less number of data buses uses a clock and data recovery method. The clock and data recovery method includes generating a clock signal, that is, a reference, from serial data and using the generated clock signal as a strobe signal for receiving data. Accordingly, a transmission apparatus can send data having information related to the clock signal, and a reception apparatus can generate a clock signal from the data and receive the data transmitted by the transmission apparatus in synchronization with the generated clock signal.

In order to minimize the distortion of a signal attributable to a noise and jitter and increase a data-effective window, the reception apparatus can compare a point of time at which the phase of the clock signal generated from the data is shifted with a point of time at which the phase of the data is shifted and control the phase of the clock signal.

### SUMMARY

In an embodiment, a clock and data recovery circuit may include a phase detection unit configured to compare a clock signal with data and generate a plurality of early phase detection signals and a plurality of late phase detection signals. The clock and data recovery circuit may also include a first filtering unit configured to generate an early enable signal and a late enable signal based on a number of early phase detection signals and a number of late phase detection signals that have been generated. The clock and data recovery circuit may also include a second filtering unit configured to generate an up signal and a down signal based on a difference between the number of times that the early enable signal has been generated and the number of times that the late enable signal has been generated. The clock and data recovery circuit may also include a phase interpolation unit configured to control the phase of the clock signal according to the up signal and the down signal.

In an embodiment, a clock and data recovery circuit may include a phase detection unit configured to compare first to fourth division clocks having a phase difference of 90 degrees with data and generate first and second early phase detection signals and first and second late phase detection signals. The clock and data recovery circuit may also include a first filtering unit configured to generate an early enable signal and a late enable signal based on a number of first and second early phase detection signals and a number of first and second late phase detection signals that have been generated. The clock and data recovery circuit may also include a second filtering unit configured to generate an up signal and a down signal based on a difference between a number of times that the early enable signal has been generated and a number of times that the late enable signal has been generated. Further, the clock and data recovery circuit may also include a phase interpolation unit configured to control the phase of the clock signal according to the up signal and the down signal.

In an embodiment, a clock and data recovery circuit may include a phase detection unit configured to catch levels of data at a plurality of phases to generate a plurality of early phase detection signals and a plurality of late phase detection signals. The clock and data recovery circuit may also include a first filtering unit configured to generate an early enable signal and a late enable signal according to the plurality of early phase detection signals and the plurality of late phase detection signals. The clock and data recovery circuit may also include a second filtering unit configured to generate an up signal and a down signal according to the early enable signal and the late enable signal. Further, the clock and data recovery circuit may also include a phase interpolation unit configured to receive the up signal and the down signal and adjust a phase of a clock signal.

### BRIEF DESCRIPTION OF THE DRAWINGS

FIG. 1 is a configuration diagram illustrating a representation of an example of a system in accordance with an embodiment.

FIG. 2 is a configuration diagram illustrating a representation of an example of a clock and data recovery circuit.

FIGS. 3A to 3G are waveforms and tables illustrating representations of examples of the operation of a phase detection unit illustrated in FIG. 2.

FIG. 4 is a block diagram schematically illustrating the configuration of a first filtering unit illustrated in FIG. 2.

FIG. 5 is a configuration diagram illustrating a representation of an example of a first phase information combination unit illustrated in FIG. 2.

FIG. 6 illustrates a block diagram of a system employing a memory controller circuit in accordance with an embodiment of the invention.

### DETAILED DESCRIPTION

Hereinafter, a clock and data recovery circuit and a system using the same will be described below with reference to the accompanying figures through various embodiments. Moreover, various embodiments are directed to a phase detection method capable of generating an accurate phase detection result regardless of the duty of data and a clock and data recovery circuit capable of filtering the results of the detection of the phases of a clock signal and data in plural steps.

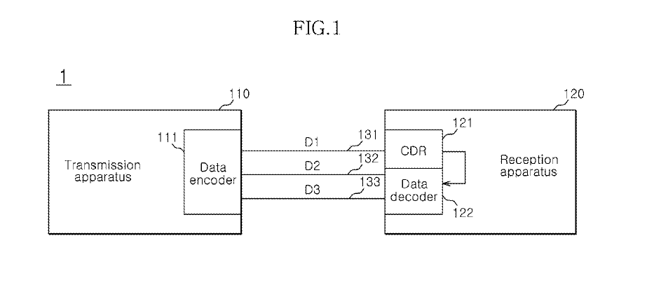

Referring to FIG. 1, a configuration diagram illustrating a representation of an example of a system in accordance with an embodiment is illustrated. In FIG. 1, the system 1 may include a transmission apparatus 110 and a reception apparatus 120. The transmission apparatus 110 may be an element representative of the side that sends data. Further, the reception apparatus 120 may be an element representative of the side that receives the data transmitted by the transmission apparatus 110. For example, the system 1 may include a master apparatus and a slave apparatus. When data is transmitted from the master apparatus to the slave apparatus, the master apparatus may be the transmission apparatus 110. In addition, the slave apparatus may be the reception apparatus 120. On the contrary, when data is transmitted from the slave apparatus to the master apparatus, the master apparatus may be the reception apparatus 120. Further, the slave apparatus may be the transmission apparatus 110.

The transmission apparatus 110 and the reception apparatus 120 that form the system 1 may perform communication using a serial data transmission method using a less number of data buses. In FIG. 1, the transmission apparatus 110 may include a data encoder 111. The reception apparatus 120 may include a clock and data recovery (CDR) circuit 121 and a data decoder 122. The transmission apparatus 110 may be electrically coupled with the reception apparatus 120 through a plurality of data buses 131, 132, and 133. In FIG. 1, the number of data buses 131, 132, and 133 has been illustrated as being 3, but is not intended to be limited. The transmission apparatus 110 may generate data D1, D2, and D3 by encoding internal data through the data encoder 111. The data D1, D2, and D3 may be sequentially transmitted in series through the data buses 131, 132, and 133. The data D1, D2, and D3 may denote data transmitted through the data buses 131, 132, and 133. In addition, the internal data may denote data used within the transmission apparatus 110 or the reception apparatus 120.

The CDR circuit 121 of the reception apparatus 120 may generate a clock signal CLK from data transmitted through the data buses 131, 132, and 133. The clock signal CLK may be used as a strobe signal. The reception apparatus 120 may receive the data D1, D2, and D3, transmitted through the data buses 131, 132, and 133, in synchronization with the clock signal CLK. The data decoder 122 may convert the data D1, D2, and D3, transmitted through the data buses 131, 132, and 133, into internal data. The data encoder 111 and the data decoder 122 may include a conversion table for converting the internal data into the data D1, D2, and D3 or the data D1, D2, and D3 into the internal data.

The CDR circuit 121 may generate the clock signal CLK from the data D1, D2, and D3. The CDR circuit 121 may also compare the clock signal CLK with the data D1, D2, and D3. Further, the CDR circuit 121 may control the phase of the clock signal CLK.

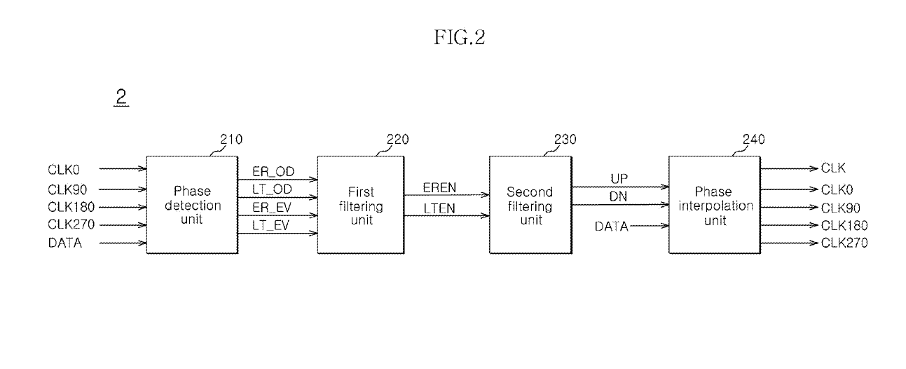

Referring to FIG. 2, a configuration diagram illustrating a representation of an example of the CDR circuit 2 is illustrated. In FIG. 2, the CDR circuit 2 may include a phase detection unit 210, a first filtering unit 220, a second filtering unit 230, and a phase interpolation unit 240. The phase detection unit 210 may compare a clock signal CLK with data DATA. The phase detection unit 210 may also generate a plurality of early phase detection signals and a plurality of late phase detection signals. The phase detection unit 210 may catch levels of the data DATA at a phase corresponding to 0 degree of the clock signal CLK; a phase corresponding to 90 degrees of the clock signal CLK; a phase corresponding to 180 degrees of the clock signal CLK; and a phase corresponding to 270 degrees of the clock signal CLK and may generate the plurality of early phase detection signals and the plurality of late phase detection signals by performing operation on the caught levels of the data DATA. To this end, the phase interpolation unit 240 may generate a plurality of division clocks each having a phase difference of 90 degrees based on the clock signal CLK. The phase detection unit 210 may compare the plurality of division clocks with the data DATA. The phase detection unit 210 may also generate the plurality of early phase detection signals and the plurality of late phase detection signals. For example, the phase detection unit 210 may detect whether an edge of the clock signal CLK is earlier or later than a point of time at which the data DATA shifts. If an edge of the clock signal CLK is earlier than a point of time at which the data DATA shifts, the phase detection unit 210 may allow the plurality of early phase detection signals to be chiefly generated. If the edge of the clock signal CLK is later than the point of time at which the data DATA shifts, the phase detection unit 210 may allow the plurality of late phase detection signals to be chiefly generated.

More specifically, the phase detection unit 210 may catch levels of the data DATA at the rising edges of first to fourth division clocks CLK0, CLK90, CLK180, and CLK270. The phase detection unit 210 may also generate first and second early phase detection signals ER_OD and ER_EV and first and second late phase detection signals LT_OD and LT_EV by performing operation on the levels of the data caught at the rising edges of the first to fourth division clocks CLK0, CLK90, CLK180, and CLK270. The operation of the phase detection unit 210 is described in more detail later.

The first filtering unit 220 may generate an early enable signal EREN and a late enable signal LTEN based on a plurality of early phase detection signals and a plurality of late phase detection signals generated by the phase detection unit 210. The first filtering unit 220 may compare the number of first and second early phase detection signals ER_OD and ER_EV that have been generated with the number of first and second late phase detection signals LT_OD and LT_EV that have been generated. The first filtering unit 210 may also generate the early enable signal EREN and the late enable signal LTEN. If the number of first and second early phase detection signals ER_OD and ER_EV that have been generated is greater than the number of first and second late phase detection signals LT_OD and LT_EV that have been generated, the first filtering unit 220 may determine that an edge of the clock signal CLK is earlier than a point of time at which the data DATA shifts and generate the early enable signal EREN. If the number of first and second late phase detection signals LT_OD and LT_EV that have been generated is greater than the number of first and second early phase detection signals ER_OD and ER_EV that have been generated, the first filtering unit 220 may determine that an edge of the clock signal CLK is later than a point of time at which the data DATA shifts and generate the late enable signal LTEN. Furthermore, if the number of first and second early phase detection signals ER_OD and ER_EV that have been generated is equal to the number of first and second late phase detection signals LT_OD and LT_EV that have been generated, the first filtering unit 220 may not generate the early enable signal EREN and the late enable signal LTEN. The first filtering unit 220 may be an average filter for determining which one of a plurality of early phase detection signals and a plurality of late phase detection signals is more generated.

The second filtering unit 230 may generate an up signal UP and a down signal DN based on the early enable signal EREN and the late enable signal LTEN. The second filtering unit 230 may generate one of the up signal UP and the down signal DN if a difference between the number of times that the early enable signal EREN has been generated and also if the number of times that the late enable signal LTEN has been generated reaches a specific number. The specific number may be the filter length (or bandwidth) of the second filtering unit 230. For example, if the filter length is 3, the second filtering unit 230 may generate one of the up signal UP and the down signal DN when a difference between the number of times that the early enable signal EREN has been generated and the number of times that the late enable signal LTEN has been generated reaches 3. If the early enable signal EREN is generated 3 times more than the late enable signal LTEN, the second filtering unit 230 may generate the down signal DN. If the late enable signal LTEN is generated 3 times more than the early enable signal EREN, the second filtering unit 230 may generate the up signal UP.

The second filtering unit 230 may accumulatively calculate the number of times that the early enable signal EREN and the late enable signal LTEN have been generated. For example, if the early enable signal, the late enable signal, the early enable signal, the early enable signal, the late enable signal, the early enable signal, and the early enable signal have been sequentially generated by the first filtering unit 220, when the fifth early enable signal is generated, the second filtering unit 230 may generate the down signal DN. The up signal UP may be a signal including information by which the phase interpolation unit 240 advances the phase of the clock signal CLK. The down signal DN may be a signal including information by which the phase interpolation unit 240 delays the phase of the clock signal CLK. The second filtering unit 230 may be a moving average filter for determining whether a difference between the number of times that the early enable signal EREN has been generated and the number of times that the late enable signal LTEN has been generated has reached a specific number.

The phase interpolation unit 240 may receive the data DATA and generate the clock signal CLK. The phase interpolation unit 240 may receive the up signal UP and down signal DN from the second filtering unit 230. The phase interpolation unit 240 may also change the phase of the clock signal CLK based on the up signal UP and the down signal DN. Furthermore, the phase interpolation unit 240 may generate the first to fourth division clocks CLK0, CLK90, CLK180, and CLK270 by dividing the clock signal CLK. The phase interpolation unit 240 may include a plurality of delay cells and may advance or delay the phase of the clock signal CLK by controlling the number of delay cells turned on or off based on the up signal UP and the down signal DN. The phase interpolation unit 240 may include a decoding circuit to generate a signal for controlling the delay cells based on the up signal UP and the down signal DN.

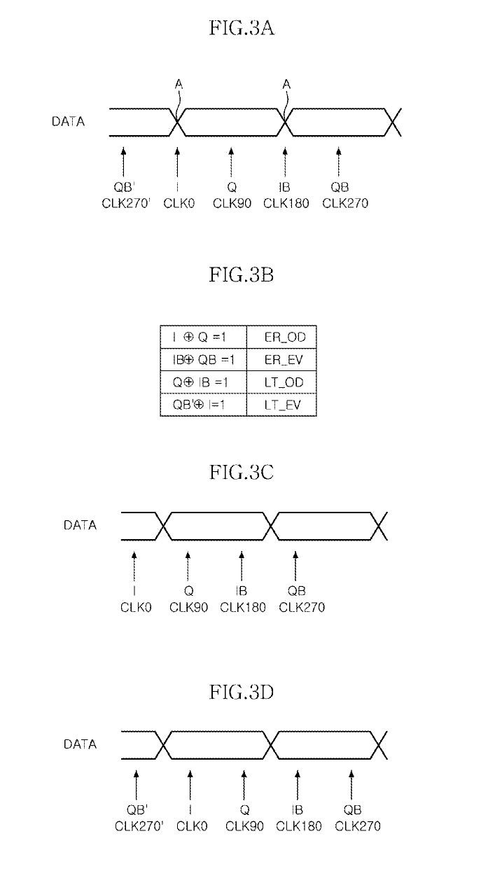

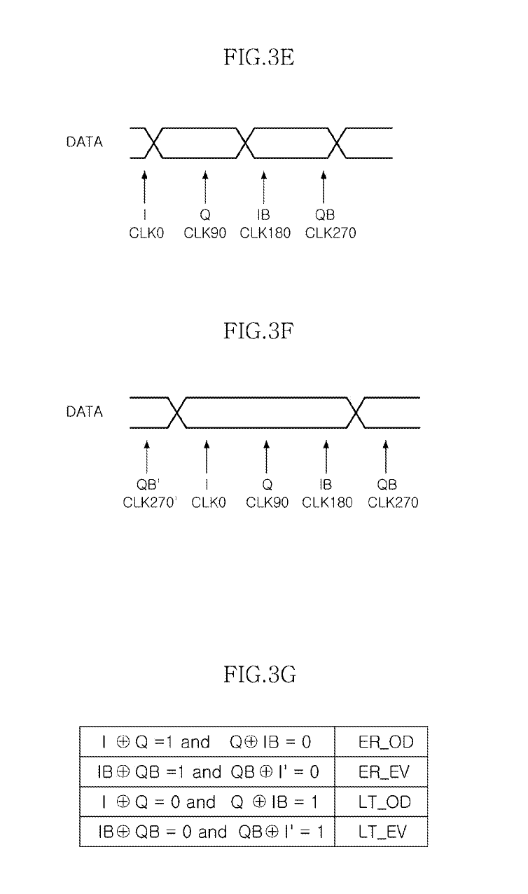

Referring to FIGS. 3a to 3g, waveforms and tables illustrating representations of examples of the operation of the phase detection unit 210 illustrated in FIG. 2 are described. The phase detection unit 210 may detect whether an edge of the clock signal CLK is earlier or later than a point of time at which the data DATA shifts. The phase detection unit 210 may catch levels of the data DATA at phases respectively corresponding to 0 degree, 90 degrees, 180 degrees, and 270 degrees of the clock signal CLK. The phase detection unit 210 may include a plurality of flip-flops for receiving the first to fourth division clocks CLK0, CLK90, CLK180, and CLK270 and the data DATA and a plurality of logic gates for performing operation on the outputs of the flip-flops.

In FIG. 3a, a timing diagram illustrating a case where the phase of the clock signal CLK does not need to be controlled, that is, a locking state is shown. In this case, the rising edges of the first and the third division clocks CLK0 and CLK180 may be the same as points A of time at which the data DATA shifts. In addition, the rising edges of the second and the fourth division clocks CLK90 and CLK270 may be placed at the central portion of the effective window of the data DATA. The fourth division clock CLK270′ may have a phase that is 90 degrees earlier than the phase of the first division clock CLK0.

The phase detection unit 210 may catch levels of the data DATA at the rising edges of the first to fourth division clocks CLK0, CLK90, CLK180, and CLK270. Further, the phase detection unit 210 may generate the first and the second early phase detection signals ER_OD and ER_EV and the first and the second late phase detection signals LT_OD and LT_EV by performing operation on caught levels I, Q, IB, QB, QB′ of the data DATA. In the table of FIG. 3b, the phase detection unit 210 may perform XOR operation on the level I of the data DATA caught at the rising edge of the first division clock CLK0 and the level Q of the data DATA caught at the rising edge of the second division clock CLK90. Further, the phase detection unit 210 may generate the first early phase detection signal ER_OD if the levels I and Q of the data DATA are different. The phase detection unit 210 may perform XOR operation on the level IB of the data DATA caught at the rising edge of the third division clock CLK180 and the level QB of the data DATA caught at the rising edge of the fourth division clock CLK270. Further, the phase detection unit 210 may generate the second early phase detection signal ER_EV if the levels IB and QB of the data DATA are different. Furthermore, the phase detection unit 210 may perform XOR operation on the level Q of the data DATA caught at the rising edge of the second division clock CLK90 and the level IB of the data DATA caught at the rising edge of the third division clock CLK180. Moreover, the phase detection unit 210 may generate the first late phase detection signal LT_OD if the levels Q and IB of the data are different. The phase detection unit 210 may perform XOR operation on the level QB′ of the data DATA caught at the rising edge of the fourth division clock CLK270′ and the caught level I of the data caught at the rising edge of the first division clock CLK0. Further, the phase detection unit 210 may also generate the second late phase detection signal LT_EV if the levels QB′ and I of the data DATA are different.

In FIG. 3c, a timing diagram illustrating a case where an edge of the clock signal CLK is earlier than a point of time at which the data DATA shifts is shown. If the data DATA is toggled, a level I of the data DATA caught at the rising edge of the first division clock CLK0 may be different from a level Q of the data DATA caught at the rising edge of the second division clock CLK90. In addition, a level IB of the data DATA caught at the rising edge of the third division clock CLK180 may be different from a level QB of the data DATA caught at the rising edge of the fourth division clock CLK270. Accordingly, the phase detection unit 210 may generate the first and the second early phase detection signals ER_OD and ER_EV. In this case, the phase detection unit 210 may not generate the first late phase detection signal LT_OD because the levels Q and IB of the data DATA caught at the rising edges of the second division clock CLK90 and the third division clock CLK180 are the same. Accordingly, since the phase detection unit 210 may generate a larger number of the early phase detection signals regardless of whether the second late phase detection signal LT_EV has been generated, it may send information indicative that an edge of the clock signal CLK is earlier than a point of time at which the data DATA shifts to the first filtering unit 220. The first filtering unit 220 may detect that a larger number of the early phase detection signals has been generated and generate the early enable signal EREN.

In FIG. 3d, a timing diagram illustrating a case where an edge of the clock signal CLK is later than a point of time at which the data DATA shifts is shown. A level I of the data DATA caught at the rising edge of the first division clock CLK0 may be the same as a level Q of the data DATA caught at the rising edge of the second division clock CLK90. In addition, a level IB of the data DATA caught at the rising edge of the third division clock CLK180 may be the same as a level QB of the data DATA caught at the rising edge of the fourth division clock CLK270. Accordingly, the phase detection unit 210 may not generate the first and the second early phase detection signals ER_OD and ER_EV. The level Q of the data caught at the rising edge of the second division clock CLK90 may be different from the level IB of the data DATA caught at the rising edge of the third division clock CLK180. Further, a level QB′ of the data DATA caught at the rising edge of the fourth division clock CLK270′ may be different from the level I of the data DATA caught at the rising edge of the first division clock CLK0. Accordingly, the phase detection unit 210 may generate the first and the second late phase detection signals LT_OD and LT_EV. The phase detection unit 210 may send information indicative that the edge of the clock signal CLK is later than the point of time at which the data DATA shifts to the first filtering unit 220 because it may generate a larger number of the late phase detection signals. The first filtering unit 220 may detect that a larger number of the late phase detection signals have been generated and generate the late enable signal LTEN.

In FIGS. 3e and 3f, timing diagrams illustrating the relationship between the clock signal CLK and the data DATA when the duty of the data DATA has been twisted, that is, when the frequency of the data DATA has not been controlled are shown. As illustrated in FIG. 3e, if the duty of the data DATA is less than 50%, a level I of the data DATA caught at the rising edge of the first division clock CLK0 may be different from a level Q of the data DATA caught at the rising edge of the second division clock CLK90. Further, the level Q of the data DATA caught at the rising edge of the second division clock CLK90 may also be different from a level IB of the data DATA caught at the rising edge of the third division clock CLK180. In this case, the phase detection unit 210 may generate the first early phase detection signal ER_OD and the first late phase detection signal LT_OD. Furthermore, the phase detection unit 210 may not generate the second early phase detection signal ER_EV because the level IB of the data DATA caught at the rising edge of the third division clock CLK180 may be the same as a level QB of the data DATA caught at the rising edge of the fourth division clock CLK270. Accordingly, the phase detection unit 210 may not generate an early phase detection signal and a late phase detection signal. In addition, the first filtering unit 220 may not generate the early enable signal EREN and the late enable signal LTEN.

If the duty of the data DATA exceeds 50% as illustrated in FIG. 3f, a level I of the data DATA caught at the rising edge of the first division clock CLK0 may be identical with a level Q of the data DATA caught at the rising edge of the second division clock CLK90. In addition, the level Q of the data DATA caught at the rising edge of the second division clock CLK90 may be identical with a level IB of the data DATA caught at the rising edge of the third division clock CLK180. Accordingly, the phase detection unit 210 may not generate the first early phase detection signal ER_OD and the first late phase detection signal LT_OD. Furthermore, the level IB of the data DATA caught at the rising edge of the third division clock CLK180 may be different from a level QB of the data DATA caught at the rising edge of the fourth division clock CLK270. In addition, a level QB′ of the data DATA caught at the rising edge of the fourth division clock CLK270′ may be different from the level I of the data DATA caught at the rising edge of the first division clock CLK0. The phase detection unit 210 may generate the second early phase detection signal ER_EV and the second late phase detection signal LT_EV. Accordingly, the phase detection unit 210 may generate the same number of early phase detection signals and late phase detection signals. Further, the first filtering unit 220 may not generate both the early enable signal EREN and the late enable signal LTEN.

If the phase detection unit 210 generates a single early phase detection signal and a single late phase detection signal, it may output an erroneous phase detection result if the duty of the data DATA has been twisted as illustrated in FIGS. 3e and 3f. For example, although an edge of the clock signal CLK is earlier than a point of time at which the data DATA shifts, the phase detection unit 210 may generate the late phase detection signal LTEN. Although an edge of the clock signal CLK is later than a point of time at which the data DATA shifts, the phase detection unit 210 may generate the early phase detection signal EREN. To prevent such a malfunction, the phase detection unit 210 may be configured to generate a plurality of phase detection signals. Furthermore, the first filtering unit 220 may be configured to determine whether a plurality of phase detection signals has been generated so that the early enable signal EREN and the late enable signal LTEN are generated based on more accurate phase information.

FIG. 3g is a table illustrating another operation of the phase detection unit 210. The phase detection unit 210 according to FIG. 3g is insensitive to the jitter or noise of the clock signal CLK and the duty or frequency of the data DATA so that an accurate phase detection result can be output. The phase detection unit 210 may generate the first early phase detection signal ER_OD when levels I and Q of the data DATA caught at the rising edges of the first division clock CLK0 and the second division clock CLK90 differ and when levels Q and IB of the data DATA caught at the rising edges of the second division clock CLK90 and the third division clock CLK180 are the same. The phase detection unit 210 may generate the second early phase detection signal ER_EV when levels IB and QB of the data DATA caught at the rising edges of the third division clock CLK180 and the fourth division clock CLK270 differ. The phase detection unit 210 may also generate the second early phase detection signal ER_EV when the levels QB and I′ of the data DATA caught at the rising edges of the fourth division clock CLK270 and a first division clock CLK0′ have phases 360 degrees later than the first division clock CLK0. In contrast, the phase detection unit 210 may generate the first late phase detection signal LT_OD when the levels I and Q of the data DATA caught at the rising edges of the first division clock CLK0 and the second division clock CLK90 are the same and the levels Q and IB of the data DATA caught at the rising edges of the second division clock CLK90 and the third division clock CLK180 differ. The phase detection unit 210 may generate the second late phase detection signal LT_EV when the levels IB and QB of the data DATA caught at the rising edges of the third division clock CLK180 and the fourth division clock CLK270 are the same. The phase detection unit 210 may also generate the second late phase detection signal LT_EV when the levels QB and I′ of the data DATA caught at the rising edges of the fourth division clock CLK270 and the first division clock CLK0′ differ.

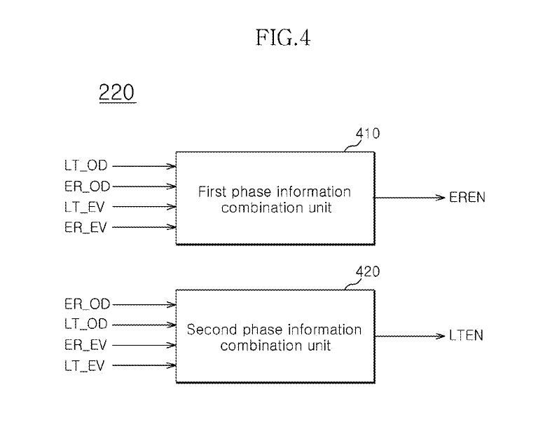

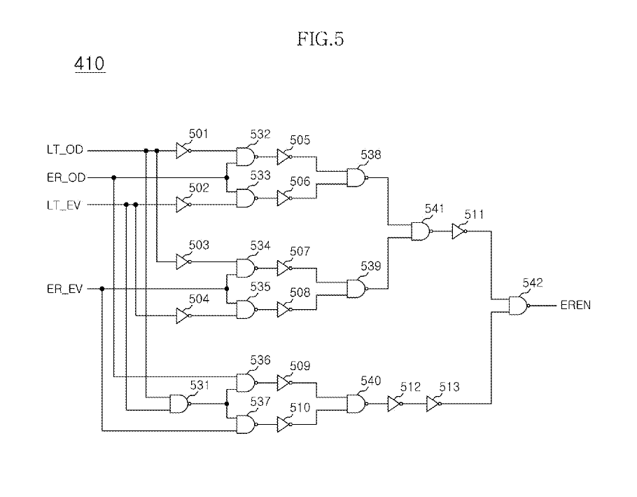

Referring to FIG. 4, a block diagram schematically illustrating the configuration of the first filtering unit 220 illustrated in FIG. 2 is described. In FIG. 4, the first filtering unit 220 may include a first phase information combination unit 410 and a second phase information combination unit 420. The first phase information combination unit 410 may receive the first and the second early phase detection signals ER_OD and ER_EV and the first and the second late phase detection signals LT_OD and LT_EV and generate the early enable signal EREN. The first phase information combination unit 410 may generate the early enable signal EREN if the number of early phase detection signals that have been generated is 1 greater than that of late phase detection signals that have been generated based on the first and the second early phase detection signals ER_OD and ER_EV and the first and the second late phase detection signals LT_OD and LT_EV. The second phase information combination unit 420 may receive the first and the second early phase detection signals ER_OD and ER_EV and the first and the second late phase detection signals LT_OD and LT_EV and generate the late enable signal LTEN. The second phase information combination unit 420 may generate the late enable signal LTEN if the number of late phase detection signals that have been generated is 1 greater than that of early phase detection signals that have been generated based on the first and the second early phase detection signals ER_OD and ER_EV and the first and the second late phase detection signals LT_OD and LT_EV.

Referring to FIG. 5, a configuration diagram illustrating a representation of an example of the first phase information combination unit 510 illustrated in FIG. 2 is shown. In FIG. 5, the first phase information combination unit 510 may include first to thirteenth inverters 501-513 and first to twelfth NAND gates 531-542. The first inverter 501 and the third inverter 503 may receive the first late phase detection signal LT_OD. In addition, the second inverter 502 and the fourth inverter 504 may receive the second late phase detection signal LT_EV. The first NAND gate 531 may receive the first late phase detection signal LT_OD and the second late phase detection signal LT_EV. The second NAND gate 532 may receive the output of the first inverter 501 and the first early phase detection signal ER_OD. The third NAND gate 533 may receive the output of the second inverter 502 and the first early phase detection signal ER_OD. The fourth NAND gate 534 may receive the output of the third inverter 503 and the second early phase detection signal ER_EV. The fifth NAND gate 535 may receive the output of the fourth inverter 504 and the second early phase detection signal ER_EV. The sixth NAND gate 536 may receive the output of the first NAND gate 531 and the first early phase detection signal ER_EV. The seventh NAND gate 537 may receive the output of the first NAND gate 531 and the second early phase detection signal ER_EV. The fifth inverter 505 may receive the output of the second NAND gate 532. The sixth inverter 506 may receive the output of the third NAND gate 533. The seventh inverter 507 may receive the output of the fourth NAND gate 534. The eighth inverter 508 may receive the output of the fifth NAND gate 535. The ninth inverter 509 may receive the output of the sixth NAND gate 536. The tenth inverter 510 may receive the output of the seventh NAND gate 537. The eighth NAND gate 538 may receive the outputs of the fifth inverter 505 and the sixth inverter 506. The ninth NAND gate 539 may receive the outputs of the seventh inverter 507 and the eighth inverter 508. The tenth NAND gate 540 may receive the outputs of the ninth inverter 509 and the tenth inverter 510. The eleventh NAND gate 541 may receive the outputs of the eighth NAND gate 538 and the ninth NAND gate 539. In addition, the eleventh inverter 511 may receive the output of the eleventh NAND gate 541. The twelfth inverter 512 may receive the output of the tenth NAND gate 540. Further, the thirteenth inverter 513 may receive the output of the twelfth inverter 512. The twelfth NAND gate 542 may receive the outputs of the eleventh inverter 511 and the thirteenth inverter 513 and generate the early enable signal EREN.

The first phase combination unit 410 may determine whether or not to generate the early enable signal EREN based on the number of times that the first and the second early phase detection signals ER_OD and ER_EV have been generated. In addition, the first phase combination unit 410 may also determine whether or not to generate the early enable signal EREN according to the number of times that the first and the second late phase detection signals LT_OD and LT_EV have been generated through the aforementioned logic circuit. The first phase combination unit 410 may be configured to enable the early enable signal EREN if the number of early phase detection signals that have been generated is 1 greater than that of late phase detection signals that have been generated. The first phase combination unit 410 illustrated in FIG. 5 is only one embodiment proposed to enable an implementation. Accordingly, various logic circuits may be configured so that the same function as that of the first phase combination unit 410 can be performed. The second phase combination unit 420 may have substantially the same configuration as the first phase combination unit 410. The second phase combination unit 420 may have substantially the same configuration as the first phase combination unit 410 of FIG. 5. Locations where the first early phase detection signal ER_OD and the first late phase detection signal LT_OD are input may be reversed. In addition, locations where the second early phase detection signal ER_EV and the second late phase detection signal LT_EV are may be reversed.

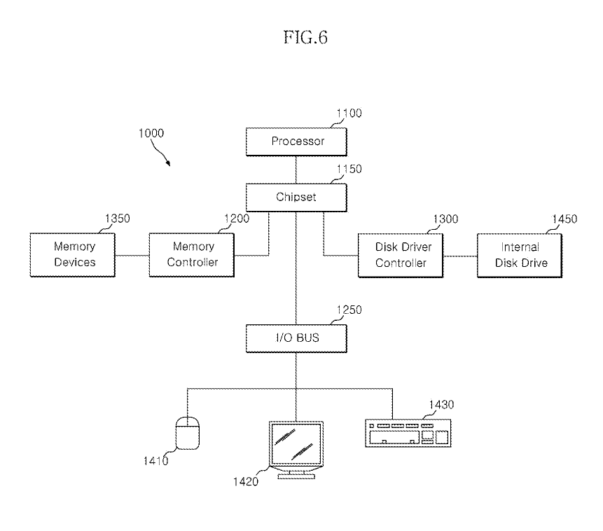

Referring to FIG. 6 a system 1000 may include one or more processors 1100. The processor 1100 may be used individually or in combination with other processors. A chipset 1150 may be electrically coupled to the processor 1100. The chipset 1150 is a communication pathway for signals between the processor 1100 and other components of the system 1000. Other components may include a memory controller 1200, an input/output (“I/O”) bus 1250, and a disk drive controller 1300. Depending on the configuration of the system 1000, any one of a number of different signals may be transmitted through the chipset 1150.

The memory controller 1200 may be electrically coupled to the chipset 1150. The memory controller 1200 can receive a request provided from the processor 1100 through the chipset 1150. The memory controller 1200 may be electrically coupled to one or more memory devices 1350. The memory devices 1350 may include the CDR circuit described above.

The chipset 1150 may also be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420 and 1430.

The disk drive controller 1300 may also be electrically coupled to the chipset 1150. The disk drive controller 1300 may serve as the communication pathway between the chipset 1150 and one or more internal disk drives 1450. The disk drive controller 1300 and the internal disk drives 1450 may communicate with each other or with the chipset 1150 using virtually any type of communication protocol.

While various embodiments have been described above, it will be understood to those skilled in the art that the embodiments described are by way of examples only. Accordingly, the CDR circuit and the system using the same described should not be limited based on the described embodiments above.

What is claimed is:

1. A clock and data recovery circuit, comprising:
a phase detection unit configured to compare a clock signal with data and generate a plurality of early phase detection signals and a plurality of late phase detection signals;
a first filtering unit configured to generate an early enable signal and a late enable signal based on a number of the plurality of early phase detection signals and a number of the plurality of late phase detection signals that have been generated;
a second filtering unit configured to generate an up signal and a down signal based on a difference between a number of times that the early enable signal has been generated and a number of times that the late enable signal has been generated; and
a phase interpolation unit configured to control a phase of the clock signal according to the up signal and the down signal.

2. The clock and data recovery circuit of claim 1, wherein the phase detection unit catches levels of the data at rising edges of division clock signals of the clock signal and generates the plurality of early phase detection signals and the late phase detection signals by performing an operation on the caught levels of the data.

3. The clock and data recovery circuit of claim 1, wherein:
the first filtering unit generates the early enable signal if the number of early phase detection signals that have been generated is more than the number of late phase detection signals that have been generated, and
the first filtering unit generates the late enable signal if the number of late phase detection signals that have been generated is less than the number of early phase detection signals that have been generated.

4. The clock and data recovery circuit of claim 1, wherein the first filtering unit does not generate the early enable signal and the late enable signal if the number of early phase detection signals that have been generated is identical with the number of late phase detection signals that have been generated.

5. The clock and data recovery circuit of claim 1, wherein the first filtering unit comprises:
a first phase information combination unit configured to generate the early enable signal if the number of early phase detection signals that have been generated is 1 more than the number of late phase detection signals that have been generated according to the plurality of early phase detection signals and the plurality of late phase detection signals; and
a second phase information combination unit configured to generate the late enable signal if the number of late phase detection signals that have been generated is 1 more than the number of early phase detection signals that have been generated according to the plurality of early phase detection signals and the plurality of late phase detection signals.

6. The clock and data recovery circuit of claim 1, wherein the second filtering unit generates one of the up signal and the down signal when the difference between the number of times that the early enable signal has been generated and the number of times that the late enable signal has been generated reaches a specific number.

7. The clock and data recovery circuit of claim 1, wherein the second filtering unit includes a moving average filter.

8. A clock and recovery circuit, comprising:
a phase detection unit configured to compare first to fourth division clocks having a phase difference of 90 degrees with data and generate first and second early phase detection signals and first and second late phase detection signals;
a first filtering unit configured to generate an early enable signal and a late enable signal based on a number of the first and the second early phase detection signals and a number of the first and the second late phase detection signals that have been generated;
a second filtering unit configured to generate an up signal and a down signal based on a difference between a number of times that the early enable signal has been generated and a number of times that the late enable signal has been generated; and
a phase interpolation unit configured to control a phase of the clock signal according to the up signal and the down signal.

9. The clock and data recovery circuit of claim 8, wherein the phase detection unit catches levels of the data at rising edges of the first to fourth division clocks and generates the first and the second early phase detection signals and the first and the second late phase detection signals by performing an operation on the caught levels of the data.

10. The clock and data recovery circuit of claim 9, wherein:
the phase detection unit generates the first early phase detection signal if the levels of the data caught at the rising edges of the first division clock and the second division clock differ, and
the phase detection unit generates the second early phase detection signal if the levels of the data caught at the rising edges of the third division clock and the fourth division clock differ.

11. The clock and data recovery circuit of claim 10, wherein:
the phase detection unit generates the first late phase detection signal if the levels of the data caught at the rising edges of the second division clock and the third division clock differ, and
the phase detection unit generates the second late phase detection signal if the levels of the data caught at the rising edges of the fourth division clock and the second division clock differ.

12. The clock and data recovery circuit of claim 9, wherein:
the phase detection unit generates the first early phase detection signal if the levels of the data caught at the rising edges of the first division clock and the second division clock differ and the level of the data caught at the rising edge of the second division clock is identical with the level of the data caught at the rising edge of the third division clock, and
the phase detection unit generates the second early phase detection signal if the levels of the data caught at the rising edges of the third division clock and the fourth division clock differ and the level of the data caught at the rising edge of the fourth division clock is identical with the level of the data caught at the rising edge of the first division clock.

13. The clock and data recovery circuit of claim 12, wherein:
the phase detection unit generates the first late phase detection signal if the level of the data caught at the rising edge of the first division clock is identical with the level of the data caught at the rising edge of the second division clock and the levels of the data caught at the rising edges of the second division clock and the third division clock differ, and
the phase detection unit generates the second late phase detection signal if the level of the data caught at the rising edge of the third division clock is identical with the level of the data caught at the rising edge of the fourth division clock and the levels of the data caught at the rising edges of the fourth division clock and the first division clock differ.

14. The clock and data recovery circuit of claim 8, wherein:
the first filtering unit generates the early enable signal if the number of first and second early phase detection signals that have been generated is more than the number of first and second late phase detection signals that have been generated, and
the first filtering unit generates the late enable signal if the number of first and second late phase detection signals that have been generated is more than the number of first and second early phase detection signals that have been generated.

15. The clock and data recovery circuit of claim 8, wherein the first filtering unit does not generate the early enable signal and the late enable signal if the number of first and second early phase detection signals that have been generated is identical with the number of first and second late phase detection signals that have been generated.

16. The clock and data recovery circuit of claim 8, wherein the first filtering unit comprises:
a first phase information combination unit configured to generate the early enable signal if the number of early phase detection signals that have been generated is 1 more than the number of late phase detection signals that have been generated according to the plurality of early phase detection signals and the plurality of late phase detection signals; and a second phase information combination unit configured to generate the late enable signal if the number of late phase detection signals that have been generated is 1 more than the number of early phase detection signals that have been generated according to the plurality of early phase detection signals and the plurality of late phase detection signals.

17. The clock and data recovery circuit of claim 8, wherein the second filtering unit generates one of the up signal and the down signal when the difference between the number of times that the early enable signal has been generated and the number of times that the late enable signal has been generated reaches a specific number.

18. The clock and data recovery circuit of claim 8, wherein the first filtering unit includes a moving average.

19. A clock and data recovery circuit, comprising:
a phase detection unit configured to catch levels of data at a plurality of phases to generate a plurality of early phase detection signals and a plurality of late phase detection signals;
a first filtering unit configured to generate an early enable signal and a late enable signal according to the plurality of early phase detection signals and the plurality of late phase detection signals;
a second filtering unit configured to generate an up signal and a down signal according to the early enable signal and the late enable signal; and
a phase interpolation unit configured to receive the up signal and the down signal and adjust a phase of a clock signal.

20. The clock and data recovery circuit of claim 19, wherein the phase interpolation unit is configured to generate a plurality of division clocks having a phase difference with each other according to the clock signal.

21. The clock and data recovery circuit of claim 20, wherein the phase detection unit is configured to compare the plurality of division clocks with the data to generate the plurality of early phase detection signals and the plurality of late phase detection signals.

22. The clock and data recovery circuit of claim 19, wherein the phase detection unit is configured to detect if an edge of the clock signal is earlier or later than a point of time at which the data is shifted.

23. The clock and data recovery circuit of claim 19, wherein the first filtering unit is configured to determine if the plurality of early phase detection signals are generated more than the plurality of last phase detection signals.

24. The clock and data recovery circuit of claim 19, wherein the second filtering unit is configured to generate one of the up signal and the down signal if a difference between a number of times that the early enable signal has been generated and a number of times that the late enable signal has been generated reaches a specific number, wherein the specific number is a filter length.
